(19) United States
(12) Patent Application Publication
(10) Pub. No.: US 2013/0057273 A1
(43) Pub. Date: Mar. 7, 2013

(54) CURRENT SENSOR

(71) Applicant: Yosuke IDE, Niigata-ken (JP)

(72) Inventor: Yosuke IDE, Niigata-ken (JP)

(73) Assignee: ALPS GREEN DEVICES CO., LTD., Tokyo (JP)

(21) Appl. No.: 13/586,757

(22) Filed: Aug. 15, 2012

(30) Foreign Application Priority Data
Sep. 2, 2011 (JP) 2011-191592

(51) Int. Cl. G01R 33/09

(52) U.S. Cl. 324/252

(57) ABSTRACT

A current sensor includes a magnetoresistive element and magnetic shields arranged between a current line and the magnetoresistive element. The magnetic shields include a flat first magnetic shield placed so as to attenuate the strength of an induction magnetic field applied to the magnetoresistive element and a flat second magnetic shield placed apart from the first magnetic shield in a direction in-plane with the main surface of the first magnetic shield so as to attenuate the strength of the induction magnetic field applied to the magnetoresistive element and reduce the influence of residual magnetization in the first magnetic shield.

### CLAIM OF PRIORITY

This application claims benefit of Japanese Patent Application No. 2011-191592 filed on Sep. 2, 2011, which is hereby incorporated by reference.

### BACKGROUND OF THE INVENTION

1. Field of the Invention

The present invention relates to current sensors measuring current in a noncontact manner.

2. Description of the Related Art

In the field of motor drive technology for electric vehicles and hybrid cars, a relatively large current is used. Current sensors capable of measuring a large current in a noncontact manner are therefore demanded. Such a current sensor has been in practical use which detects a change in magnetic field, caused by a current to be measured (hereinafter, also referred to as a “target current”), using a magnetic sensor. Some current sensors of this type include a member that serves as a shield against an external magnetic field in order to reduce the external magnetic field applied to the magnetic sensor (refer to PCT Japanese Translation Patent Publication No. 2000-516714, for example). Such a shield reduces the strength of a magnetic field applied to the magnetic sensor, so that the upper limit of magnetic field strength which can be actually measured is increased. Thus, the current measurement range of the current sensor can be extended.

The above-described shield has hysteresis in magnetism. If an external magnetic field reduced by the shield is applied to the magnetic sensor, an output of the sensor will have hysteresis. Disadvantageously, the accuracy of current measurement decreases. An approach has been proposed which reduces the width of a shield in the direction of a magnetic field so as to reduce the hysteresis of the shield in order to prevent the current measurement accuracy from decreasing. A reduction in width of the shield in the magnetic field direction increases the shape anisotropy (shape magnetic anisotropy) of the shield. The hysteresis can therefore be reduced. Consequently, the decrease of the current measurement accuracy caused by the hysteresis of the shield can be prevented.

The above-described reduction in width of the shield in the magnetic field direction, however, leads to a reduction in area of the shield. The effect of reducing the magnetic field is also lowered. Disadvantageously, it is difficult to sufficiently extend the current measurement range of the current sensor.

### SUMMARY OF THE INVENTION

The present invention has been made in consideration of the above-described disadvantages. The present invention provides a current sensor including magnetic shields capable of reducing an external magnetic field and suppressing the influence of hysteresis.

According to an aspect of the present invention, a current sensor includes a magnetoresistive element detecting an induction magnetic field from a target current flowing through a current line and magnetic shields arranged between the current line and the magnetoresistive element. The magnetic shields include a flat first magnetic shield placed so as to attenuate the strength of the induction magnetic field applied to the magnetoresistive element and a flat second magnetic shield placed apart from the first magnetic shield in a direction in-plane with the main surface of the first magnetic shield so as to attenuate the strength of the induction magnetic field applied to the magnetoresistive element and reduce the influence of residual magnetization in the first magnetic shield.

In this structure, since the magnetic shields include the flat first magnetic shield and the flat second magnetic shield placed apart from the first magnetic shield, an external magnetic field can be reduced as compared with a structure in which a first magnetic shield alone constitutes a magnetic shield. Furthermore, since the flat second magnetic shield placed apart from the first magnetic shield can reduce the influence of residual magnetization in the first magnetic shield, the influence of hysteresis can be suppressed as compared with the structure in which the first magnetic shield alone constitutes the magnetic shield. Thus, the current sensor can be achieved which includes the shields capable of reducing an external magnetic field and suppressing the influence of hysteresis.

In this aspect, the current sensor may further include a feedback coil generating a cancelling magnetic field so as to cancel out the induction magnetic field that the magnetoresistive element detects.

In the current sensor according to this aspect, preferably, the second magnetic shield is placed apart from the first magnetic shield in a direction of the induction magnetic field. This arrangement enables the external magnetic field to be further reduced, so that the influence of hysteresis can be further suppressed.

In the current sensor according to this aspect, preferably, the width of the second magnetic shield in a direction perpendicular to the direction of the induction magnetic field is greater than or equal to the width of the first magnetic shield in the direction perpendicular to the direction of the induction magnetic field. This arrangement enables the shape anisotropy of the second magnetic shield to be greater than that of the first magnetic shield. Accordingly, the saturation magnetic field of the second magnetic shield is greater than that of the first magnetic shield. Advantageously, the external magnetic field can be more effectively reduced.

In the current sensor according to this aspect, the width of the second magnetic shield in a direction parallel to the direction of the induction magnetic field is less than or equal to the width of the first magnetic shield in the direction parallel to the direction of the induction magnetic field. This arrangement enables the shape anisotropy of the second magnetic shield to be greater than that of the first magnetic shield. Accordingly, the saturation magnetic field of the second magnetic shield is greater than that of the first magnetic shield. Advantageously, the external magnetic field can be more effectively reduced.

In the current sensor according to this aspect, preferably, the distance between the first magnetic shield and the second magnetic shield is in the range of 2 μm to 40 μm. This arrangement enables the influence of hysteresis to be sufficiently suppressed.

### BRIEF DESCRIPTION OF THE DRAWINGS

FIG. 1 is a schematic diagram of an exemplary structure of a magnetic balance current sensor according to an embodiment of the present invention;

FIG. 2 is a plan view of specific components of the magnetic balance current sensor according to the embodiment;

FIG. 3 is an enlarged view of a magnetoresistive element in the embodiment;

FIG. 4 is a schematic cross-sectional view of a laminated structure of the magnetic balance current sensor according to the embodiment;

FIGS. 5A and 5B are schematic cross-sectional views of a magnetic balance current sensor including no second magnetic shields and the magnetic balance current sensor according to the embodiment for comparison between the influences of hysteresis in the current sensors;

FIGS. 6A and 6B are schematic diagrams illustrating a simulation model for determination of advantages achieved by the embodiment;

FIG. 7 is a characteristic diagram illustrating the relationship between the presence or absence of the second magnetic shields and the effective magnetic field strength applied to magnetoresistive elements; and

FIG. 8 is a characteristic diagram illustrating the relationship between the distance between a first magnetic shield and each second magnetic shield and the effective magnetic field strength and the relationship between the distance therebetween and the hysteresis of the magnetic shields.

### DESCRIPTION OF THE PREFERRED EMBODIMENTS

The inventor found that designing a current sensor including a magnetoresistive element and magnetic shields such that the magnetic shields include a first magnetic shield placed in a region covering the magnetoresistive element and a second magnetic shield placed near, or apart from the first magnetic shield reduces an external magnetic field while suppressing the influence of hysteresis of the magnetic shields. An embodiment of the present invention will be described in detail below with reference to the drawings.

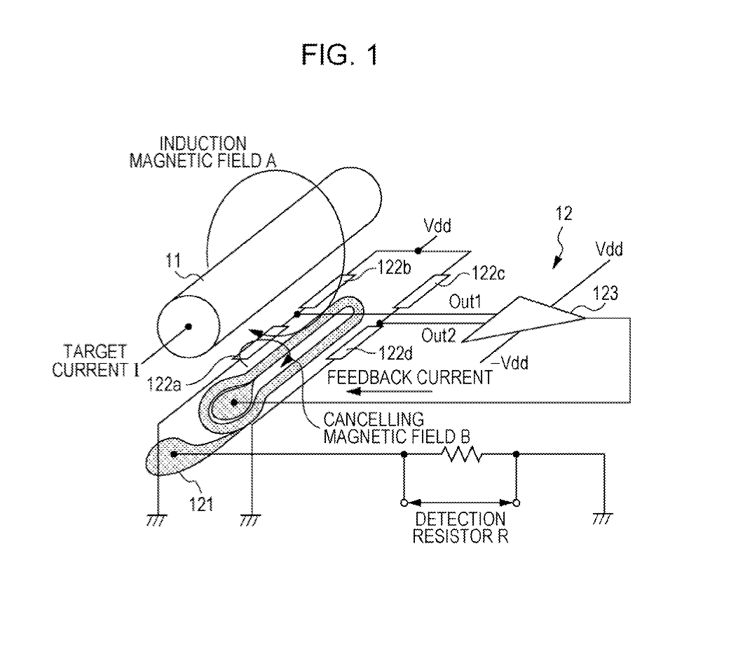

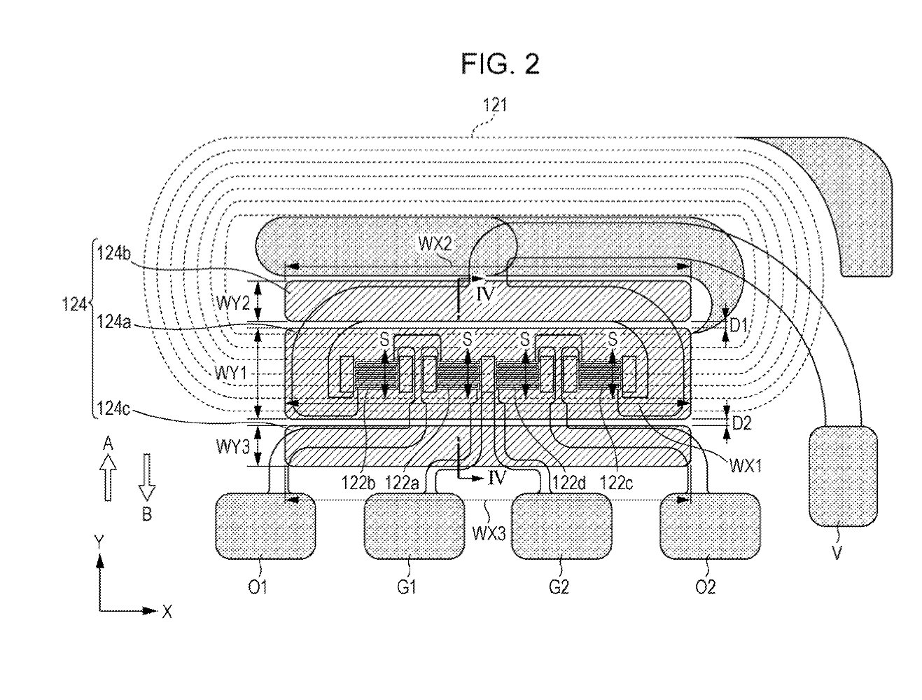

FIG. 1 is a schematic diagram of an exemplary structure of a magnetic balance current sensor according to the embodiment. FIG. 1 principally illustrates the connection relationship between magnetoresistive elements 122a to 122d constituting the magnetic balance current sensor. The specific structure of each element and the arrangement of the elements will be described in detail later with reference to FIG. 2 and subsequent figures. Referring to FIG. 1, the magnetic balance current sensor according to this embodiment is placed near a conductor (current line) 11 through which a target current I flows. This magnetic balance current sensor includes a feedback circuit 12 that generates a cancelling magnetic field B which cancels out an induction magnetic field A caused by the target current I. The feedback circuit 12 includes a feedback coil 121 and the four magnetoresistive elements 122a to 122d. While this embodiment relates to the magnetic balance current sensor, the present invention is applicable to magnetic proportional current sensors including no feedback coil 121.

The feedback coil 121, having a flat spiral pattern, can generate the cancelling magnetic field B oriented in the opposite direction from the induction magnetic field A when current flows through the pattern.

The magnetoresistive elements 122a to 122d each have a resistance varying upon application of an external magnetic field. For example, giant magnetoresistance (GMR) elements or tunnel magnetoresistance (TMR) elements can be used. In the magnetic balance current sensor according to this embodiment, the magnetoresistive elements 122a to 122d are connected in predetermined relation to constitute a magnetic field detection bridge circuit that detects fluctuations of an external magnetic field. The use of the magnetic field detection bridge circuit including the magnetoresistive elements 122a to 122d achieves the magnetic balance current sensor capable of detecting the induction magnetic field A caused by the target current I with high sensitivity. The configuration of the magnetic field detection bridge circuit is not limited to that illustrated in FIG. 1. The magnetic field detection bridge circuit may include a fixed resistor whose resistance is not changed due to an external magnetic field.

In the magnetic field detection bridge circuit illustrated in FIG. 1, the connection point between the magnetoresistive elements 122b and 122c is connected to a power supply which applies a power supply voltage Vdd. In addition, one end of the magnetoresistive element 122a and that of the magnetoresistive element 122d are connected to ground which applies a ground voltage GND. A first output voltage Out1 is obtained from the connection point between the magnetoresistive elements 122a and 122b and a second output voltage Out2 is obtained from the connection point between the magnetoresistive elements 122c and 122d. The difference between two output voltages corresponds to an external magnetic field applied to the magnetoresistive elements 122a to 122d.

The difference between the first output voltage Out1 and the second output voltage Out2 is amplified by an amplifier 123 and is then supplied as a current (feedback current) to the feedback coil 121. In other words, the feedback current has a magnitude corresponding to the difference between the first output voltage Out1 and the second output voltage Out2. When the feedback current flows through the feedback coil 121, the cancelling magnetic field B is generated around the feedback coil 121 so as to cancel out the induction magnetic field A caused by the target current I. In a state in which the induction magnetic field A is strong, the voltage difference in the magnetic field detection bridge circuit is large, such that the feedback current flowing through the feedback coil 121 increases. Accordingly, the cancelling magnetic field B also increases. In a state in which the induction magnetic field A is weak, the voltage difference in the magnetic field detection bridge circuit is small, such that the feedback current flowing though the feedback coil 121 decreases. Accordingly, the cancelling magnetic field B also decreases. As described above, the feedback coil 121 generates the cancelling magnetic field B that cancels the induction magnetic field A out. A detection resistor R, functioning as a detector, calculates the target current I on the basis of a value of the feedback current in a balanced state where the induction magnetic field A and the cancelling magnetic field B cancel each other out.

FIG. 2 is a plan view of specific components of the magnetic balance current sensor according to the embodiment. The magnetoresistive elements 122a to 122d each including a magnetic detection pattern (hereinafter, referred to as “elongated pattern segments”) extending in the X direction are arranged in the order of the magnetoresistive elements 122b, 122a, 122d, and 122c at the center of FIG. 2. In each of the magnetoresistive elements 122a to 122d, the direction (hereinafter, referred to as the “sensitivity axis direction”) S in which the magnetic detection sensitivity is the highest is the direction (Y direction) perpendicular to the extending direction (X direction) of the elongated pattern segments. Accordingly, the magnetoresistive elements 122a to 122d are arranged such that the direction S (i.e., the Y direction perpendicular to the extending direction of the elongated pattern segments), serving as the sensitivity axis direction, coincides with the orientation of the induction magnetic field A from the target current I flowing through the current line 11.

The magnetoresistive elements 122a to 122d are connected to various terminals (electrodes) by wiring. For example, the magnetoresistive element 122b is connected to a power supply terminal V to which the power supply is connected and a first output terminal O1. The magnetoresistive element 122a is connected to a ground terminal G1 to which the ground is connected and the first output terminal O1. The magnetoresistive element 122d is connected to a ground terminal G2 to which the ground is connected and a second output terminal O2. The magnetoresistive element 122c is connected to the power supply terminal V and the second output terminal O2. The specific components, including the magnetoresistive elements 122a to 122d, wiring, and the various terminals (electrodes), of the magnetic balance current sensor are not limited to those illustrated in FIG. 2.

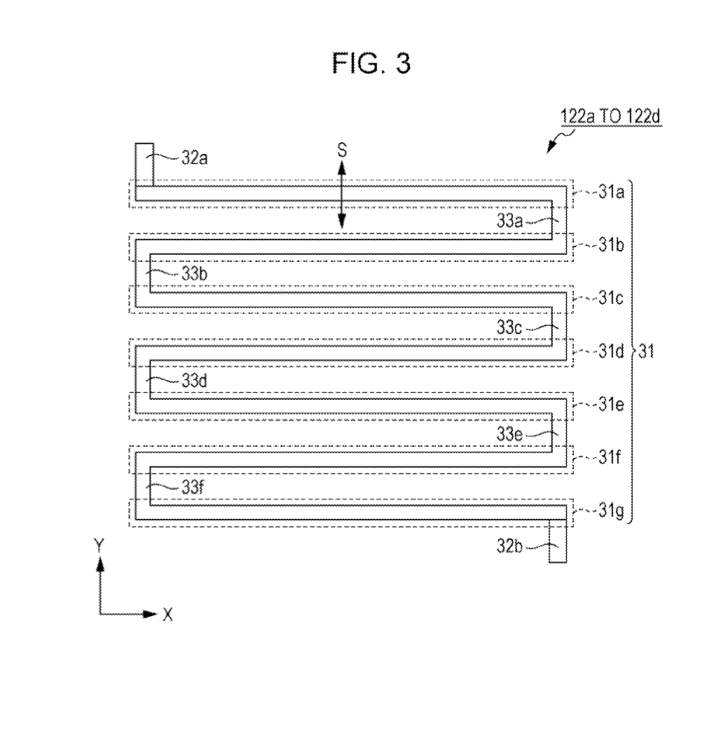

FIG. 3 is an enlarged view of any one of the magnetoresistive elements 122a to 122d in the embodiment. Referring to FIG. 3, the magnetoresistive elements 122a to 122d each include the magnetic detection pattern including a plurality of elongated pattern segments 31 such that the elongated pattern segments 31 are arrayed in substantially parallel to one another in the direction (Y direction) perpendicular to the longitudinal direction (X direction) of the elongated pattern segments 31. In FIG. 3, the sensitivity axis direction (direction S) is the direction (Y direction) orthogonal to the longitudinal direction of the elongated pattern segments 31. Accordingly, the magnetoresistive elements 122a to 122d are arranged such that the direction along the induction magnetic field A and the cancelling magnetic field B applied to the magnetoresistive elements 122a to 122d coincides with the direction S (i.e., the Y direction). While FIG. 3 illustrates the magnetic detection pattern including seven elongated pattern segments 31a to 31g, the number of elongated pattern segments 31 is not limited to seven.

One end (left end in FIG. 3) of the outermost elongated pattern segment 31a is connected to a connection terminal 32a in the array direction (Y direction) of the elongated pattern segments 31. One end (right end in FIG. 3) of the elongated pattern segment 31g farthest from the elongated pattern segment 31a in the array direction of the elongated pattern segments 31 is connected to a connection terminal 32b on the opposite side from the one end of the elongated pattern segment 31a.

The other end of the elongated pattern segment 31a is connected to a corresponding end of the elongated pattern segment 31b next to the elongated pattern segment 31a by a connecting portion 33a. The other end of the elongated pattern segment 31b is connected to a corresponding end of the next elongated pattern segment 31c by a connecting portion 33b. Similarly, the other end of the elongated pattern segment 31c is connected to a corresponding end of the next elongated pattern segment 31d by a connecting portion 33c. The other end of the elongated pattern segment 31d is connected to a corresponding end of the next elongated pattern segment 31e by a connecting portion 33d. The ends of the elongated pattern segments 31 are connected to the next elongated pattern segments 31 by the connecting portions 33a to 33f, respectively, in the above-described manner. Thus, the magnetic detection pattern is meandering-shaped.

When current flows from the power supply (power supply voltage Vdd) to the ground (ground voltage GND) through the above-described meandering-shaped magnetic detection pattern, a voltage drop occurs in the meandering-shaped magnetic detection pattern in accordance with its electrical resistance. Since the electric resistance of the meandering-shaped magnetic detection pattern varies depending on an external magnetic field, the voltage drop in the magnetic detection pattern varies in accordance with the induction magnetic field A and the cancelling magnetic field B. One of the connection terminals 32a and 32b of the magnetic detection pattern is connected to one of the first output terminal O1 and the second output terminal O2 by wiring. Thus, a voltage corresponding to the voltage drop in the magnetic detection pattern is obtained as the first output voltage Out1 or the second output voltage Out2.

Referring again to FIG. 2, the feedback coil 121 in the spiral winding pattern is placed above the magnetoresistive elements 122a to 122d (or on the front of the drawing sheet of FIG. 2), with an insulating film therebetween. The winding pattern of the feedback coil 121 is placed so as to overlap the magnetoresistive elements 122a to 122d located below (or at the back of the drawing sheet) in plan view. The winding pattern of the feedback coil 121 is positioned so as to extend in substantially parallel to the extending direction (X direction) of the elongated pattern segments in a region covering the magnetoresistive elements 122a to 122d. Accordingly, the feedback coil 121 can generate the cancelling magnetic field B in the direction (Y direction) substantially perpendicular to the extending direction of the elongated pattern segments. Specifically, the orientation of the cancelling magnetic field B applied to the magnetoresistive elements 122a to 122d coincides with the sensitivity axis direction of the magnetoresistive elements 122a to 122d in the region covering the magnetoresistive elements 122a to 122d. Note that the specific structure of the feedback coil 121 is not limited to that illustrated in FIG. 2 in the magnetic balance current sensor.

A flat first magnetic shield 124a, which comprises a high-permeability material, is placed above the feedback coil 121 (or on the front of the drawing sheet of FIG. 2) with an insulating layer therebetween in the region covering the magnetoresistive elements 122a to 122d. In addition, a second magnetic shield 124b and a second magnetic shield 124c are positioned near the first magnetic shield 124a such that the second magnetic shields 124b and 124c are arranged apart from the first magnetic shield 124a. The second magnetic shields 124b and 124c may be arranged apart from the first magnetic shield 124a in the direction (Y direction) orthogonal to the extending direction of the elongated pattern segments of the magnetoresistive elements 122a to 122d (or the extending direction of the winding pattern of the feedback coil 121). In other words, the second magnetic shields 124b and 124c may be arranged apart from the first magnetic shield 124a in the direction along the induction magnetic field A and the cancelling magnetic field B.

Each of the first magnetic shield 124a and the second magnetic shields 124b and 124c is substantially rectangular in plan view such that the longitudinal direction of the rectangle coincides with the extending direction (X direction) of the elongated patter segments of the magnetoresistive elements 122a to 122d. In other words, the direction perpendicular to the longitudinal direction coincides with the direction (Y direction) perpendicular to the extending direction of the elongated pattern segments of the magnetoresistive elements 122a to 122d. The first magnetic shield 124a has a width (length) WY1 parallel to the induction magnetic field A and the cancelling magnetic field B and a width (length) WX1 perpendicular to the induction magnetic field A and the cancelling magnetic field B in plan view such that the width WY1 is shorter than the width WX1. Furthermore, the second magnetic shield 124b has a width WY2 parallel to the induction magnetic field A and the cancelling magnetic field B and a width (length) WX2 perpendicular to the induction magnetic field A and the cancelling magnetic field B such that the width WY2 is shorter than the width WX2. In addition, the second magnetic shield 124c has a width (length) WY3 parallel to the induction magnetic field A and the cancelling magnetic field B and a width (length) WX3 perpendicular to the induction magnetic field A and the cancelling magnetic field B such that the width WY3 is shorter than the width WX3. In the case where the first magnetic shield 124a and the second magnetic shields 124b and 124c have the shorter widths WY1, WY2, and WY3 in the magnetic field direction as described above, the shape anisotropy (shape magnetic anisotropy) of each shield increases. Thus, the hysteresis can be suppressed.

In the magnetic balance current sensor according to the embodiment, the magnetic shields 124 reduce the strength of the induction magnetic field A applied to the magnetoresistive elements 122a to 122d. Consequently, the upper limit of magnetic field strength to be actually measured is raised, so that the current measurement range of the magnetic balance current sensor can be extended. In addition, since the first magnetic shield 124a is disposed apart from the second magnetic shields 124b and 124c in the direction along the induction magnetic field A and the cancelling magnetic field B, if magnetization remains in the first magnetic shield 124a under the influence of the induction magnetic field A and the cancelling magnetic field B and the residual magnetization causes a reflux magnetic field, the reflux magnetic field generated from the first magnetic shield 124a can be shielded by the second magnetic shields 124b and 124c. Accordingly, the influence of the reflux magnetic field on the magnetoresistive elements 122a to 122d by the first magnetic shield 124a can be suppressed. In other words, the current measurement range of the current sensor can be extended by reducing the strength of the induction magnetic field A and the influence of the hysteresis of the first magnetic shield 124a can be diminished.

Furthermore, in the magnetic balance current sensor according to the embodiment, the widths WY2 and WY3 of the second magnetic shields 124b and 124c in the direction parallel to the induction magnetic field A and the cancelling magnetic field B applied on the magnetoresistive elements 122a to 122d are shorter than the width WY1 of the first magnetic shield 124a in that direction. In addition, the widths WX2 and WX3 of the second magnetic shields 124b and 124c in the direction perpendicular to the induction magnetic field A and the cancelling magnetic field B applied to the magnetoresistive elements 122a to 122d are equal to the width WX1 of the first magnetic shield 124a in that direction. This arrangement enables the shape anisotropy of each of the second magnetic shields 124b and 124c to be greater than that of the first magnetic shield 124a. Accordingly, the saturation magnetic field of each of the second magnetic shields 124b and 124c is greater than that of the first magnetic shield 124a. Thus, magnetization does not tend to remain in the second magnetic shields 124b and 124c as compared with in the first magnetic shield 124a. Consequently, magnetization remains in the first magnetic shield 124a. If a reflux magnetic field is caused due to the residual magnetization, the influence of the reflux magnetic field on the magnetoresistive elements 122a to 122d can be suppressed by the second magnetic shields 124b and 124c. In other words, the influence of the hysteresis of the first magnetic shield 124a can be further suppressed.

The widths WY2 and WY3 of the second magnetic shields 124b and 124c in the direction parallel to the induction magnetic field A and the cancelling magnetic field B may be less than or equal to the width WY1 of the first magnetic shield 124a in that direction. Alternatively, the width WX2 and WX3 of the second magnetic shields 124b and 124c in the direction perpendicular to the induction magnetic field A and the cancelling magnetic field B may be greater than or equal to the width WX1 of the first magnetic shield 124a in that direction. In such a case, the shape anisotropy of each of the second magnetic shields 124b and 124c can be similarly greater than that of the first magnetic shield 124a. In this case, therefore, the influence of the hysteresis of the first magnetic shield 124a can be further diminished.

The distance, D1, between the first magnetic shield 124a and the second magnetic shield 124b and the distance, D2, between the first magnetic shield 124a and the second magnetic field 124c are preferably in the range of 2 μm to 40 μm, because the influence of hysteresis can be particularly effectively suppressed in this range. While the two second magnetic shields 124b and 124c are arranged so as to sandwich the first magnetic shield 124a therebetween in this embodiment, only either one of the second magnetic shields 124b and 124c may be placed. Alternatively, a plurality of second magnetic shields may be arranged instead of each of the second magnetic shields 124b and 124c.

In the magnetic balance current sensor according to this embodiment, the above-described magnetic shields 124 function as magnetic yokes for the cancelling magnetic field B. Consequently, the strength of the cancelling magnetic field B applied to the magnetoresistive elements 122a to 122d is increased. If a current flowing through the feedback coil 121 is small, therefore, the cancelling magnetic field B having a sufficient strength can be generated. As described above, the magnetic balance current sensor according to this embodiment offers the effect of reducing power consumption.

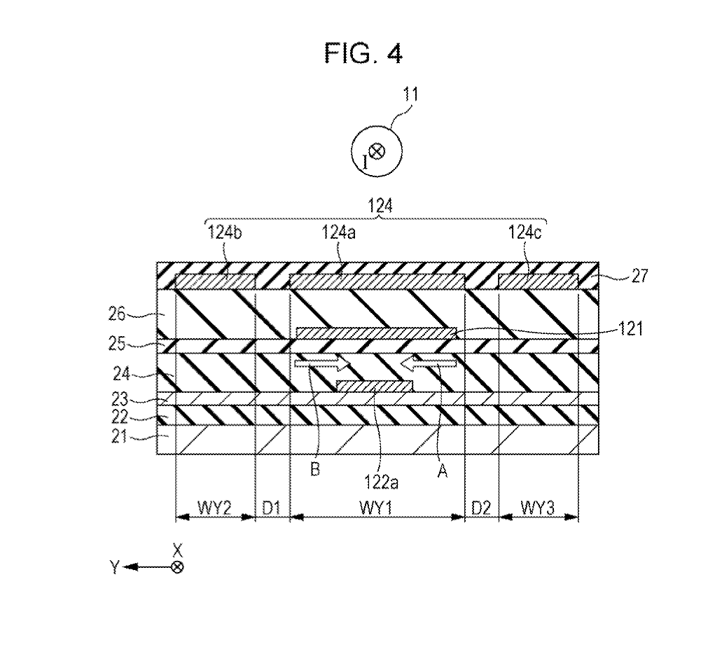

FIG. 4 is a schematic cross-sectional view of the laminated structure of the magnetic balance current sensor. The cross-section of FIG. 4, taken along the line indicated by arrows IV in FIG. 2, includes the feedback coil 121, the magnetoresistive element 122a, and the magnetic shields 124. In FIG. 4, the feedback coil 121 and the magnetoresistive element 122a are simplified for illustration of the whole laminated structure and the components, such as wiring, are partly omitted.

Referring to FIG. 4, a thermal silicon oxide layer 22, functioning as an insulating layer, is disposed on a substrate 21 which comprises silicon. An aluminum oxide layer 23 is placed on the thermal silicon oxide layer 22. The magnetoresistive element 122a is positioned on the aluminum oxide layer 23. While the magnetoresistive element 122a is illustrated as a single block in FIG. 4, the magnetoresistive element 122a actually includes the elongated pattern segments extending in the X direction such that the pattern segments are arrayed in the Y direction.

The feedback coil 121 is positioned above the magnetoresistive element 122a, with a polyimide layer 24 and a silicon oxide layer 25 therebetween. The polyimide layer 24 can be formed by, for example, applying and hardening a polyimide material. The silicon oxide layer 25 can be formed by, for example, sputtering or plasma CVD. The feedback coil 121 can be formed such that, for example, a layer comprising a conductive material, e.g., metal is formed and the layer is patterned by photolithography and etching. While the feedback coil 121 is illustrated as a single block in FIG. 4, the feedback coil 121 actually includes a plurality of winding pattern segments extending in the X direction such that the pattern segments are arrayed in the Y direction.

A polyimide layer 26 is placed so as to cover the feedback coil 121. The magnetic shields 124 are arranged on the polyimide layer 26, the magnetic shields 124 including the first magnetic shield 124a overlying the magnetoresistive element 122a in plan view and the second magnetic shields 124b and 124c arranged apart from the first magnetic shield 124a in the X direction. The magnetic shields 124 may comprise a high-permeability material, such as an amorphous magnetic material, a permalloy, or an iron microcrystalline material. A silicon oxide layer 27 is disposed on the polyimide layer 26 and the magnetic shields 124.

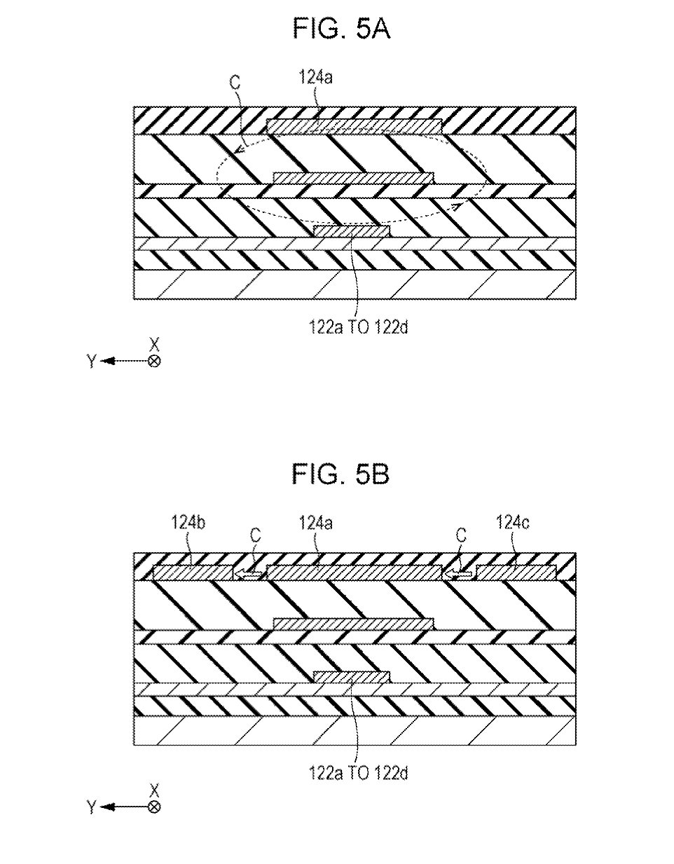

FIGS. 5A and 5B are schematic cross-sectional views of a magnetic balance current sensor including no second magnetic shields 124b and 124c and the magnetic balance current sensor according to the embodiment for comparison between the influences of hysteresis in those current sensors. FIG. 5A illustrates the magnetic balance current sensor including no second magnetic shields 124b and 124c. FIG. 5B illustrates the magnetic balance current sensor according to the embodiment.

Referring to FIG. 5A, in the case where magnetization remains in the first magnetic shield 124a in the magnetic balance current sensor including no second magnetic shields 124b and 124c, a reflux magnetic field C generated by the residual magnetization directly affects the magnetoresistive elements 122a to 122d. In this case, the current measurement accuracy of the magnetic balance current sensor significantly decreases due to the influence of the reflux magnetic field C. In the magnetic balance current sensor according to the embodiment, the reflux magnetic field C generated by the residual magnetization in the first magnetic shield 124a is absorbed by the second magnetic shields 124b and 124c arranged apart from the first magnetic shield 124a as illustrated in FIG. 5B. Accordingly, the reflux magnetic field C hardly affects the magnetoresistive elements 122a to 122d in the magnetic balance current sensor according to the embodiment.

As described above, since the magnetic balance current sensor according to the embodiment includes the first magnetic shield 124a and the second magnetic shields 124b and 124c arranged apart therefrom, the influence of hysteresis of the first magnetic shield 124a can be diminished. Consequently, a decrease in current measurement accuracy can be avoided in the magnetic balance current sensor including the magnetic shields for extension of the current measurement range.

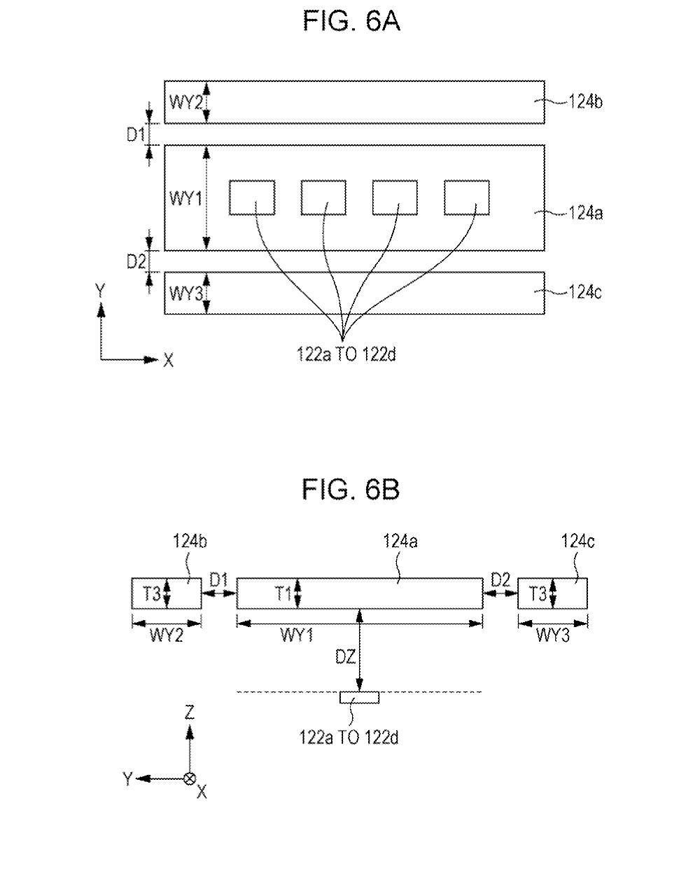

FIGS. 6A and 6B are schematic diagrams illustrating a simulation model for determination of advantages offered by the embodiment. Referring to FIG. 6A, the first magnetic shield 124a is disposed so as to overlie the magnetoresistive elements 122a to 122d in plan view. In addition, the second magnetic shields 124b and 124c are arranged apart from the first magnetic shield 124a in the direction (Y direction) along an external magnetic field as illustrated in FIGS. 6A and 6B. The simulation was done on the assumption that the external magnetic field was 300 Oe.

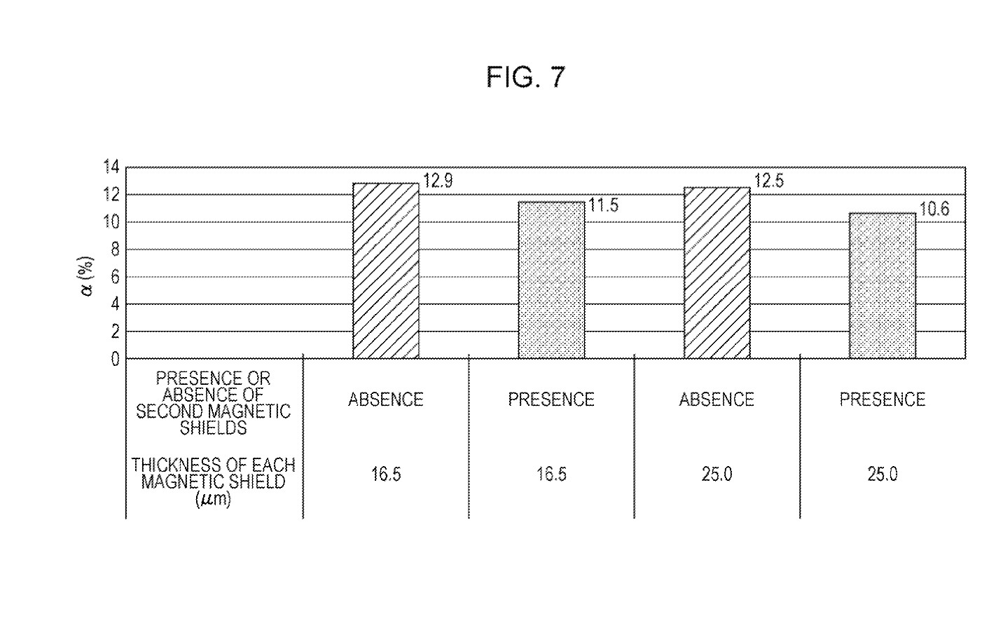

FIG. 7 is a characteristic diagram illustrating the relationship between the presence or absence of the second magnetic shields 124b and 124c and the effective magnetic field strength applied to the magnetoresistive elements 122a to 122d. The effective magnetic field strengths applied to the magnetoresistive elements 122a to 122d were evaluated using the ratio α (%) of the effective magnetic field strength to the external magnetic field strength. The value a was calculated from resistance changes ΔR/Rmin under various conditions on the basis of a reference resistance change ΔR/Rmin caused in the magnetoresistive elements 122a to 122d in the case without the magnetic shields 124 (i.e., the case without the first magnetic shield 124a and the second magnetic shields 124b and 124c).

The distance, indicated by DZ, (distance in the Z direction) between the first magnetic shield 124a and the magnetoresistive elements 122a to 122d was 13.5 μm. The width WY1 of the first magnetic shield 124a in the Y direction was 200 μm. Under the condition with the second magnetic shields 124b and 124c, each of the widths WY2 and WY3 of the second magnetic shields 124b and 124c in the Y direction was 100 μm and each of the distance D1 between the first magnetic shield 124a and the second magnetic shield 124b and the distance D2 between the first magnetic shield 124a and the second magnetic shield 124c was 10 μm. Furthermore, each of the thickness T1 of the first magnetic shield 124a and the thicknesses T2 and T3 of the second magnetic shields 124b and 124c was 16.5 μm or 25 μm.

FIG. 7 demonstrates that the ratio α of the effective magnetic field strength to the external magnetic field strength decreases as the thicknesses T1, T2, and T3 increase. Furthermore, FIG. 7 demonstrates that the ratio α of the effective magnetic field strength to the external magnetic field strength in the case with the second magnetic shields 124b and 124c is lower than that in the case without the second magnetic shields 124b and 124c. Accordingly, it was found that the second magnetic shields 124b and 124c can reduce the strength of an induction magnetic field applied to the magnetoresistive elements 122a to 122d.

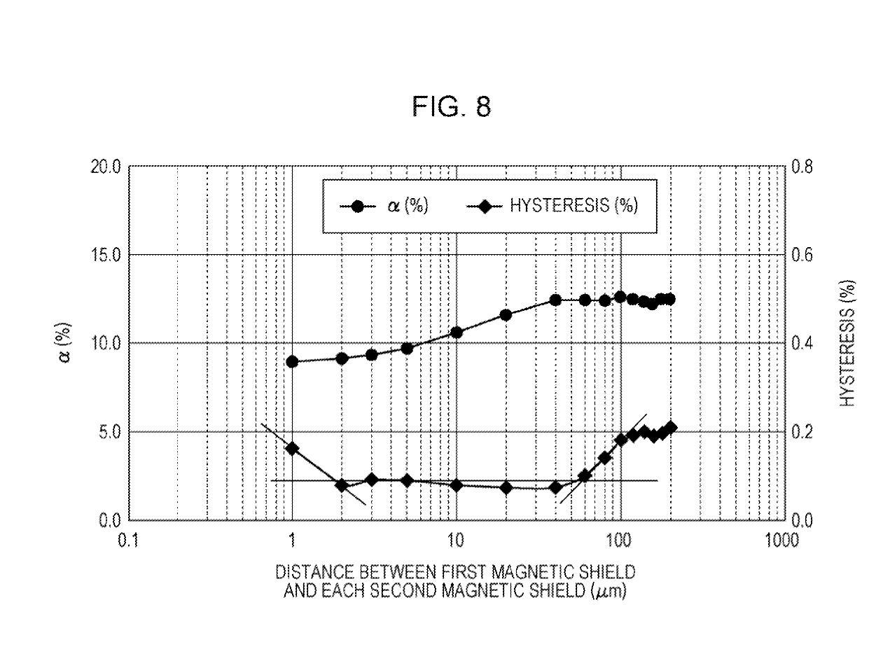

FIG. 8 is a characteristic diagram illustrating the relationship between the effective magnetic field strength and each of the distance D1 between the first magnetic shield 124a and the second magnetic shield 124b and the distance D2 between the first magnetic shield 124a and the second magnetic shield 124c and the relationship between the hysteresis of the magnetic shields 124 and the distances D1 and D2. The distance DZ (i.e., the distance in the Z direction) between the first magnetic shield 124a and the magnetoresistive elements 122a to 122d was 13.5 μm and the width WY1 of the first magnetic shield 124a in the Y direction was 200 μm as in FIG. 7. Furthermore, each of the widths WY2 and WY3 of the second magnetic shields 124b and 124c in the Y direction was 100 μm and each of the thickness T1 of the first magnetic shield 124a and the thicknesses T2 and T3 of the second magnetic shields 124b and 124c was 25 μm.

FIG. 8 demonstrates that as the distance D1 between the first magnetic shield 124a and the second magnetic shield 124b and the distance D2 between the first magnetic shield 124a and the second magnetic shield 124c increase, the ratio α of the effective magnetic field strength to the external magnetic field increases. This means that the increase of the distances D1 and D2 lowers the effect of reducing the magnetic field by the second magnetic shields 124b and 124c. Furthermore, the hysteresis of the magnetic shields 124 is sufficiently small in the case where the distances D1 and D2 are in the range of 2 μm to 40 μm. Preferably, the distance D1 between the first magnetic shield 124a and the second magnetic shield 124b and the distance D2 between the first magnetic shield 124a and the second magnetic shield 124c are in the range of 2 μm to 40 μm from the viewpoint of suppression of the influence of hysteresis.

As described above, since the magnetic shields include the first magnetic shield and the second magnetic shields arranged apart from the first magnetic shield in the current sensor according to the embodiment of the present invention, an external magnetic field can be reduced as compared with a structure in which a first magnetic shield alone constitutes a magnetic shield. Furthermore, since the second magnetic shields arranged apart from the first magnetic shield can reduce the influence of residual magnetization in the first magnetic shield, the influence of hysteresis can be suppressed as compared with the structure in which the first magnetic shield alone constitutes the magnetic shield. Consequently, the current sensor can be achieved which includes the shields capable of reducing an external magnetic field and suppressing the influence of hysteresis.

The present invention is not limited to the above-described embodiment and various modifications can be made. For example, a layer included in the current sensor according to the above-described embodiment may be added or omitted within the bounds of not affecting functions of the current sensor.

The current sensor according to the embodiment of the present invention can be used to determine the magnitude of current for driving a motor of, for example, an electric vehicle or a hybrid car.

1. A current sensor comprising:
a magnetoresistive element configured to detect an induction magnetic field from a target current flowing through a current line; and
flat magnetic shields arranged between the current line and the magnetoresistive element so as to attenuate strength of the induction magnetic field applied to the magnetoresistive element,
wherein the flat magnetic shields include:
a first magnetic shield placed above the magnetoresistive element; and
at least one second magnetic shield placed in plane with a main surface of the first magnetic shield and apart from the first magnetic shield so as to reduce influence of residual magnetization in the first magnetic shield.

2. The current sensor according to claim 1, further comprising:
a feedback coil configured to generate a cancelling magnetic field so as to cancel out the induction magnetic field detected by the magnetoresistive element.

3. The current sensor according to claim 1, wherein the second magnetic shield is placed apart from the first magnetic shield in a direction of the induction magnetic field.

4. The current sensor according to claim 1, wherein a width of the second magnetic shield in a direction perpendicular to a direction of the induction magnetic field is greater than or equal to a width of the first magnetic shield in the direction perpendicular to the direction of the induction magnetic field.

5. The current sensor according to claim 1, wherein a width of the second magnetic shield in a direction parallel to a direction of the induction magnetic field is smaller than or equal to a width of the first magnetic shield in the direction parallel to the direction of the induction magnetic field.

6. The current sensor according to claim 1, wherein a distance between the first magnetic shield and the second magnetic shield is in the range of 2 μm to 40 μm.

7. The current sensor according to claim 1, wherein the at least one second magnetic shield includes:
a pair of magnetic shields between which the first magnetic shield is disposed.

8. The current sensor according to claim 1, wherein the magnetoresistive element has a sensitive axis in a first direction which is parallel to a direction of the induction magnetic field to be detected,
and wherein a width of the second magnetic shield in a second direction perpendicular to the first direction is greater than or equal to a width of the first magnetic shield in the second direction.

9. The current sensor according to claim 8, wherein a width of the second magnetic shield in the first direction is smaller than or equal to a width of the first magnetic shield in the first direction.

10. The current sensor according to claim 2, wherein the feedback coil is disposed between the magnetoresistive element and the flat magnetic shields.
